(19) United States
(12) Patent Application Publication
(10) Pub. No.: US 2016/0358688 A1
(43) Pub. Date: Dec. 8, 2016

(54) CONDUCTIVE PASTE, METHOD OF PRODUCING PATTERN, METHOD OF PRODUCING CONDUCTIVE PASTE, AND SENSOR

(71) Applicant: TORAY INDUSTRIES, INC., Tokyo (JP)

(72) Inventor: Miharu Tanabe, Otsu-shi (JP)

(21) Appl. No.: 15/117,744

(22) PCT Filed: Feb. 5, 2015
(86) PCT No.: PCT/JP2015/053229

§ 371 Date: Aug. 10, 2016

(30) Foreign Application Priority Data
Feb. 12, 2014 (JP) 2014-024085

(51) Int. Cl. H01B 1/22; H05K 3/02; G06F 3/041; G03F 7/20; G03F 7/32; G03F 7/40; H05K 1/09; C09D 5/24

(52) U.S. Cl. CPC H01B 1/22; H05K 1/092; H05K 3/027; C09D 5/24; G03F 7/20; G03F 7/32; G03F 7/40; G03F 7/2024; G06F 3/041; H05K 2201/0218; H05K 2203/0514; G06F 2203/04103

(57) ABSTRACT

There is a need to address the problem of providing a conductive paste which is low cost in addition to being capable of forming a conductive pattern which dramatically suppresses the occurrence of ion migration. The conductive paste is one containing a photosensitive organic compound and silver-coated particles obtained by coating a conductive core with silver, wherein the proportion which silver constitutes in the silver-coated particles is 10-45 mass %.

### TECHNICAL FIELD

This disclosure relates to a conductive paste, a method of producing a pattern, a method of producing a conductive pattern, and a sensor.

### BACKGROUND

So-called polymer-type conductive pastes obtained by mixing a large amount of silver flakes, copper powder or carbon particles with a resin or an adhesive have come into practical use as materials to form an organic-inorganic composite conductive pattern, which contain a resin as an organic component and a conductive filler as an inorganic component.

For most of those conductive pastes, a conductive pattern can be obtained by heating and curing a pattern formed by screen printing method (Japanese Patent Laid-open Publication Nos. 2012-018783 and 2007-207567). However, it is difficult to accurately form a conductive pattern with a width of 100 μm or less.

Thus, conductive pastes capable of being acid-etched (Japanese Patent Laid-open Publication No. H10-064333), and photosensitive curable conductive pastes containing silver particles as conductive particles (see Japanese Patent Laid-open Publication No. 2004-361352 and International Publication No. WO 2004/061006) have been developed.

However, conductive pastes capable of being acid-etched have the problem that production steps are complicated because it is necessary to form a resist layer in forming a conductive pattern.

A high-fineness conductive pattern with a width of 100 μm or less can be formed with a conventional photosensitive curable conductive paste. However, there is the problem that silver particles to be used are expensive, and a conductive pattern is short-circuited due to an ion migration phenomenon.

Thus, it could be helpful to provide an inexpensive conductive paste capable of forming a conductive pattern in which occurrence of an ion migration phenomenon is remarkably suppressed.

### SUMMARY

We thus provide:
(1) A conductive paste including: silver-coated particles in which a conductive core is coated with silver; and a photosensitive organic compound, wherein the ratio of silver to the silver-coated particles is 10 to 45% by mass.
(2) The conductive paste according to (1), wherein the conductive core contains copper.
(3) The conductive paste according to (1) or (2), wherein the ratio of the silver-coated particles to the total solid content is 40 to 80% by mass.
(4) A method of producing a pattern, the method including applying the conductive paste according to any one of (1) to (3) onto a substrate, and exposing and developing the conductive paste to obtain a pattern with a line width of 2 to 50 μm.
(5) A method of producing a conductive pattern, the method including applying the conductive paste according to any one of (1) to (3) onto a substrate, exposing and developing the conductive paste to obtain a pattern with a line width of 2 to 50 μm, and heating the pattern at 100 to 300° C. to obtain a conductive pattern.
(6) A method of producing a conductive pattern, the method including applying the conductive paste according to any one of (1) to (3) onto a substrate, exposing and developing the conductive paste to obtain a pattern with a line width of 2 to 50 μm, and exposing the resulting pattern to light from a xenon flash tube to obtain a conductive pattern.
(7) A sensor including a conductive pattern produced using the conductive paste according to any one of (1) to (3).
(8) A sensor including a conductive pattern produced by the method of producing a conductive pattern according to (5) or (6).

Our conductive paste is inexpensive, and capable of forming a high-fineness conductive pattern in which occurrence of an ion migration phenomenon is remarkably suppressed.

### DETAILED DESCRIPTION

Our conductive paste includes silver-coated particles in which a conductive core is coated with silver; and a photosensitive organic compound, wherein the ratio of silver to the silver-coated particles is 10 to 45% by mass.

A conductive pattern formed by a method of producing a conductive pattern is a composite of an organic component and an inorganic component, where, when the conductive pattern is heated at 100 to 300° C. or exposed to light from a xenon flash tube, a photosensitive organic compound as the organic component is cured and shrunk to cause silver-coated particles as the inorganic component to come into contact with one another, and thus conductivity is exhibited.

The conductive paste includes silver-coated particles in which a conductive core is coated with silver.

By using particles having a configuration in which a conductive core is coated with silver, occurrence of an ion migration phenomenon in a conductive pattern formed can be suppressed as compared to when particles formed of only silver are used. The ion migration phenomenon refers to a phenomenon in which a metal component affected by an electric field moves over the surface or through the inside of a non-metal substance under a low temperature of lower than 100° C. Silver is known to most frequently cause an ion migration phenomenon among metals that are often used electrically. When silver or the like contained in the conductive pattern moves over the surface or through the inside of an insulating material in the ion migration phenomenon, the conductive pattern may be short-circuited due to a reduction in insulation resistance value.

The conductive core refers to a particle of a substance having an electrical conductivity. The conductive core is preferably a metal core having a satisfactory electrical conductivity. Examples of the metal that forms the conductive core include copper, lead, tin, nickel, zinc, aluminum, tungsten, molybdenum, ruthenium oxide, chromium, titanium, indium, particles of alloys of these metals, and composites of these metals. From the viewpoint of conductivity and costs, copper, zinc, nickel, aluminum and alloys thereof are preferable, and copper, zinc, nickel and alloys thereof are more preferable. Particularly, it is preferable that the conductive core contains copper. In an alloy of copper and zinc or an alloy of copper and nickel, the ratio of zinc or nickel to the conductive core is preferably 1 to 50% by mass for preventing oxidation of the copper component.

The volume average particle size of silver-coated particles is preferably 0.1 to 10 μm, more preferably 0.5 to 6 μm. When the volume average particle size is 0.1 μm or more, the contact probability of silver-coated particles in heating at 100 to 300° C. or exposure to light from a xenon flash tube increases so that the resistivity and breakage probability of a conductive pattern formed decrease. Further, in exposure of a coating film of a conductive paste applied onto a substrate, light for exposure can smoothly pass through the coating film so that fine patterning is facilitated. On the other hand, when the volume average particle size is 10 μm or less, the surface smoothness, pattern accuracy and dimensional accuracy of a conductive pattern formed are improved. The volume average particle size can be measured by a Coulter counter method.

The ratio of silver to silver-coated particles should be 10 to 45% by mass. When the ratio of silver to silver-coated particles is 10% by mass or more, a conductive pattern having a low resistivity and high stability can be formed. Further, it is preferable that the ratio of silver to silver-coated particles is 20% by mass or more because a pattern having a lower resistivity can be formed. On the other hand, when the ratio of silver to silver-coated particles is more than 45% by mass, the cost of silver-coated particles increases, and the effect of suppressing an ion migration phenomenon is reduced. When the ratio of silver to silver-coated particles is 10 to 45% by mass, the viscosity of the conductive paste can be properly controlled.

The ratio of silver to silver-coated particles and the composition of the conductive core can be determined by making a measurement by a X-ray fluorescence analyzer (ZSX Priumus manufactured by Rigaku Corporation) under a vacuum atmosphere using a sample prepared by applying a load to silver-coated particles to form the particles into a pellet shape.

As a coating form of silver-coated particles, it is preferable that the surface of the conductive core is fully coated to suppress a chemical reaction of the conductive core with a photosensitive organic compound or the like contained in the conductive paste. The surface of the conductive core may be partially coated, or the silver coating film may be provided with a hole. When the conductive paste contains a photosensitive organic compound having a carboxyl group, and the conductive core contains an easily cationically ionizable metal such as copper, zinc or nickel, the conductive core and the carboxyl group may be bonded to each other leading to a considerable increase in viscosity of the conductive paste or gelation of the conductive paste. Accordingly, it is preferable that the surface of the conductive core is sufficiently coated with silver that is chemically stable.

Examples of the method of coating the conductive core with silver include a chemical reduction method using a substitution reaction between the conductive core and silver, another chemical reduction method in which silver or a silver precursor is precipitated on the surface of the conductive core using a reducing agent together, and a physical method in which silver particles are electrically adsorbed to the conductive core, and firmly bonded to the conductive core with a pressure. These chemical reduction methods are preferable because the circumference of the conductive core is uniformly coated with silver, and even particles having a small particle size are easily coated. In the chemical reduction method using a substitution reaction, when the conductive core contains an easily ionizable metal, a substitution reaction between the easily ionizable metal and silver easily takes place, leading to further improvement of coating efficiency. For example, when copper in the conductive core further contains zinc or nickel that is easily ionizable, the conductive core is easily uniformly coated with silver. Accordingly, it is practical to use silver-coated particles prepared by a chemical reduction method using a substitution reaction.

Examples of the silver compound to be used to coat the conductive core include silver salts such as silver nitrate, silver acetate and silver chloride. Preferably, the silver salt is dissolved in water or an organic solvent, and used. A reducing agent, a chelating agent and a pH adjuster may be added as additives.

The ratio of silver-coated particles to the solid content in the conductive paste is preferably 40 to 80% by mass. When the ratio of silver-coated particles to the solid content is 40% by mass or more, the contact probability of silver-coated particles in heating at 100 to 300° C. or exposure to light from a xenon flash tube increases so that the resistivity and breakage probability of a conductive pattern formed decrease. On the other hand, when the ratio of silver-coated particles to the solid content is 80% by mass or less, light for exposure can smoothly pass through the coating film so that fine patterning is facilitated. The total solid content refers to all constituents of the conductive paste excluding the solvent.

The photosensitive organic compound (hereinafter, referred to as a “compound (A)”) contained in the conductive paste refers to a monomer, an oligomer or a polymer which contains one or more unsaturated double bond. Examples of the compound (A) include acryl-based copolymers. The acryl-based copolymer refers to a copolymer containing as a copolymer component an acryl-based monomer having a carbon-carbon double bond.

Examples of the acryl-based monomer having a carbon-carbon double bond include acryl-based monomers such as methyl acrylate, acrylic acid, 2-ethylhexyl acrylate, ethyl methacrylate, n-butyl acrylate, iso-butyl acrylate, iso-propane acrylate, glycidyl acrylate, N-methoxymethylacrylamide, N-ethoxymethylacrylamide, N-n-butoxymethylacrylamide, N-isobutoxymethylacrylamide, isobutoxymethylacrylamide, butoxy triethylene glycol acrylate, dicyclopentanyl acrylate, dicyclopentenyl acrylate, 2-hydroxyethyl acrylate, isobornyl acrylate, 2-hydroxypropyl acrylate, isodexyl acrylate, isooctyl acrylate, lauryl acrylate, 2-methoxyethyl acrylate, methoxyethylene glycol acrylate, methoxydiethylene glycol acrylate, octafluoropentyl acrylate, phenoxyethyl acrylate, stearyl acrylate, trifluoroethyl acrylate, acrylamide, aminoethyl acrylate, phenyl acrylate, phenoxyethyl acrylate, 1-naphthyl acrylate, 2-naphthyl acrylate, thiophenol acrylate and benzylmercaptan acrylate; styrenes such as styrene, p-methylstyrene, o-methylstyrene, m-methylstyrene, α-methyl styrene, chloromethyl styrene and hydroxymethyl styrene; γ-methacryloxypropyltrimethoxysilane; 1-vinyl-2-pyrrolidone; allylated cyclohexyl diacrylate; 1,4-butanediol diacrylate; 1,3-butylene glycol diacrylate; ethylene glycol diacrylate; diethylene glycol diacrylate; triethylene glycol diacrylate; polyethylene glycol diacrylate; dipentaerythritol hexaacrylate; dipentaerythritol monohydroxypentaacrylate; ditrimethylolpropane tetraacrylate; glycerol diacrylate; methoxylated cyclohexyl diacrylate; neopentylglycol diacrylate; propylene glycol diacrylate; polypropylene glycol diacrylate; triglycerol diacrylate; trimethylolpropane triacrylate; epoxy acrylate monomers such as acrylic acid adducts of ethylene glycol diglycidyl ether, acrylic acid adducts of diethylene glycol diglycidyl ether, acrylic acid adducts of neopentyl glycol diglycidyl ether, acrylic acid adducts of glycerin diglycidyl ether, acrylic acid adducts of bisphenol A diglycidyl ether, acrylic acid adducts of bisphenol F and acrylic acid adducts of cresol novolac each having a hydroxyl group formed by ring-opening an epoxy group with an unsaturated acid; and compounds in which the acrylic group of the acryl-based monomer is replaced by a methacrylic group.

Among them, acryl-based monomers having a back bone selected from the group consisting of a bisphenol A backbone, a bisphenol F backbone, a bisphenyl backbone and a hydrogenated bisphenol A backbone are preferable for ensuring that a conductive pattern formed has a moderate hardness.

An alkali-soluble acryl-based copolymer soluble in an alkaline developer and the like is obtained by using as a monomer an unsaturated acid such as an unsaturated carboxylic acid. Examples of the unsaturated acid include acrylic acid, methacrylic acid, itaconic acid, crotonic acid, maleic acid, fumaric acid, vinyl acetate, and acid anhydrides of these acids. The acid value of the resulting acryl-based copolymer can be adjusted by increasing or decreasing the amount of an unsaturated acid to be used.

By reacting carboxyl groups of the acryl-based copolymer with a compound containing an unsaturated double bond such as glycidyl (meth)acrylate, an alkali-soluble acryl-based copolymer containing a reactive unsaturated double bond on the side chain is obtained.

The acid value of the compound is preferably 40 to 250 mg KOH/g to ensure that the compound has optimum alkali-solubility. When the acid value is less than 40 mg KOH/g, the solubility of the soluble moiety decreases. On the other hand, when the acid value is more than 250 mg KOH/g, the development allowance range is narrowed. The acid value of the compound can be measured in accordance with JIS K 0070 (1992).

Preferably, the conductive paste contains a nitrogen-containing compound. The nitrogen-containing compound (hereinafter, referred to as a “compound (B)”) refers to a compound selected from the group consisting of imidazole, triazole, ethyleneimine and an oxime compound. When the conductive paste contains the compound (B), a conductive pattern having a low resistivity at a low temperature can be formed. Specifically, the compound (B) is more dominantly bonded to the surfaces of silver-coated particles in comparison with other organic components, or unevenly distributed over the surfaces of the particles so that the dispersibility of the silver-coated particles can be improved to form a pattern which is fine and excellent in conductivity. When as another organic component, one containing a carboxyl group is used, the above-mentioned effect can be more remarkably achieved when the compound (B)coexists than when the compound (B) is not contained. A time-dependent increase in viscosity of the conductive paste and a time-dependent change such as gelation can be suppressed. The compound (B) is also effective when coating is insufficient due to existence of a hole in the silver coating film on the surface of the conductive core.

Examples of the compound (B) include 2-hydroxy-4-(2-hydroxy-3-methacryloxy)propoxybenzophenone, benzotriazole-based compounds such as 2-(2′-hydroxy-5′-methyl-phenyl)benzotriazole, 2-(2′-hydroxy-3′,5′-di-t-butylphenyl)benzotriazole, 2-(2′-hydroxy-3′-t-butyl-5′-methylphenyl)-5-chlorobenzotriazole, 2-(2′-hydroxy-3′-5′-di-t-butylphenyl)-5-chloro-benzotriazole and 2-(2′-hydroxy-4′-n-octoxyphenyl)benzotriazole, N-(2-aminoethyl)piperazine; 1-(2-aminoethyl)-4-methylpiperazine hydrochloride; 6-amino-1-methyluracil, polyethylene-imine; octadecyl isocyanate-modified polyethyleneimine; propylene oxide-modified polyethyleneimine; and oxime ester compounds such as 1,2-octanedione-1-[4-(phenylthio)-2-]O-benzoyloxime)], ethanone-1-[9-ethyl-6-(2-methylbenzoyl)-9-H-carbazole-3-yl]-1-(acetyloxime) and 2-(acetyloximinomethyl)thioxanthene-9-one.

The added amount of the compound (B) based on 100 parts by mass of the compound (A) is preferably 0.01 to 20 parts by mass. When added amount of the compound (B) based on 100 parts by mass of the compound (A) is 0.01 part by mass or more, the conductivity of the pattern can be exhibited in heating at a lower temperature, and a time-dependent increase in viscosity of the conductive paste and a time-dependent change such as gelation can be suppressed. On the other hand, when the added amount of the compound (B) is 20 parts by mass or less, fine patterning is facilitated.

Preferably, the conductive paste contains a thermosetting compound (hereinafter, referred to as a “compound (C)”). Examples of the compound (C) include epoxy resins, novolac resins, phenol resins, polyimide precursors and ring-closed polyimides. Epoxy resins are preferable to improve adhesion to the substrate and forming a conductive pattern having high stability. By appropriately selecting a backbone of the epoxy resin, the rigidity, stiffness and flexibility of the pattern can be controlled. Examples of the epoxy resin include ethylene glycol-modified epoxy resins, bisphenol A-type epoxy resins, brominated epoxy resins, bisphenol F-type epoxy resins, hydrogenated bisphenol A-type epoxy resins, hydrogenated bisphenol F-type epoxy resins, novolac-type epoxy resins, cycloaliphatic epoxy resins, glycidylamine-type epoxy resins, glycidyl ether-type epoxy resins and heterocyclic epoxy resins.

The added amount of the compound (C) based on 100 parts by mass of the compound (A) is preferably 1 to 100 parts by mass, more preferably 10 to 80 parts by mass, further preferably 30 to 80 parts by mass. When the added amount of the compound (C) based on 100 parts by mass of the compound (A) is 1 part by mass or more, adhesion to the substrate is improved. On the other hand, when the added amount of the compound (C) is 100 parts by mass or less, a conductive pattern having stability can be formed.

Preferably, the conductive paste contains a photopolymerization initiator. The photopolymerization initiator refers to a compound which generates radicals by absorbing short-wavelength light such as an ultraviolet ray to be decomposed or by undergoing a hydrogen-withdrawing reaction. Examples of the photopolymerization initiator include 1,2-octanedione, 1-[4-(phenylthio)-2-(O-benzoyloxime)], 2,4,6-trimethylbenzoyl-diphenyl-phosphine oxide, bis(2,4,6-trimethylbenzoyl)-phenyl-phosphine oxide, ethanone, 1-[9-ethyl-6-2(2-methylbenzoyl)-9H-carbazole-3-yl]-1-(O-acetyloxime), benzophenone, methyl o-benzoylbenzoate, 4,4′-bis(dimethylamino)benzophenone, 4,4′-bis(diethylamino)benzophenone, 4,4′-dichlorobenzophenone, 4-benzoyl-4′-methyldiphenylketone, dibenzylketone, fluorenone, 2,2′-diethoxyacetophenone, 2,2-dimethoxy-2-phenylacetophenone, 2-hydroxy-2-methylpropiophenone, p-t-butyldichloroacetophenone, thioxanthone, 2-methylthioxanthone, 2-chlorothioxanthone, 2-isopropylthioxanthone, diethylthioxanthone, benzyl, benzyl dimethyl ketal, benzyl-β-methoxyethyl acetal, benzoin, benzoin methyl ether, benzoin butyl ether, anthraquinone, 2-t-butylanthraquinone, 2-amylanthraquinone, β-chloroanthraquinone, anthrone, benzanthrone, dibenzosuberone, methylene anthrone, 4-azidebenzalacetophenone, 2,6-bis(p-azidebenzylidene)cyclohexanone, 6-bis(p-azidebenzylidene)-4-methylcyclohexanone, 1-phenyl-1,2-butanedione-2-(o-methoxycarbonyl)oxime, 1-phenyl-propanedione-2-(o-ethoxycarbonyl)oxime, 1-phenyl-propanedione-2-(o-benzoyl)oxime, 1,3-diphenyl-propanetrione-2-(o-ethoxycarbonyl)oxime, 1-phenyl-3-ethoxy-propanetrione-2-(o-benzoyl)oxime, Michler's ketone, 2-methyl-[4-(methylthio)phenyl]-2-morpholino-1-propanone, naphthalenesulfonyl chloride, quinolinesulfonyl chloride, N-phenylthioacridone, 4,4′-azobisisobutyronitrile, diphenyl disulfide, benzothiazole disulfide, triphenylphosphine, camphor quinone, 2,4-diethylthioxanthone, isopropylthioxanthone, carbon tetrabromide, tribromophenylsulfone, benzoyl peroxide, and combinations of a photo-reductive pigment such as eosin and methylene blue, and a reducing agent such as ascorbic acid and triethanolamine.

The added amount of the photopolymerization initiator based on 100 parts by mass of the compound (A) is preferably 0.05 to 30 parts by mass, more preferably 5 to 20 parts by mass. When the added amount of the photopolymerization initiator based on 100 parts by mass of the compound (A) is 0.05 parts by mass or more, the curing density of an exposed part of coating film of the conductive paste increases so that the residual film ratio after developing increases. On the other hand, when the added amount of the photopolymerization initiator is 30 parts by mass or less, excessive absorption of light at the upper part of the coating film of the conductive paste is suppressed. As a result, the formed conductive pattern is inhibited from being reversely tapered to suppress reduction in adhesion to the substrate.

The conductive paste may contain a sensitizer along with the photopolymerization initiator.

Examples of the sensitizer include 2,4-diethylthioxanthone, isopropylthioxanthone, 2,3-bis(4-diethylaminobenzal)cyclopentanone, 2,6-bis(4-dimethylaminobenzal)cyclohexanone, 2,6-bis(4-dimethylaminobenzal)-4-methylcyclohexanone, Michler's ketone, 4,4-bis(diethylamino)benzophenone, 4,4-bis(dimethylamino)chalcone, 4,4-bis(diethyl amino)chalcone, p-dimethyl-aminocinnamylideneindanone, p-dimethylaminobenzylideneindanone, 2-(p-dimethyl amino-phenylvinylene)isonaphthothiazole, 1,3-bis(4-dimethylaminophenylvinylene)isonaphthothiazole, 1,3-bis(4-dimethylaminobenzal)acetone, 1,3-carbonylbis(4-diethylaminobenzal)acetone, 3,3-carbonylbis(7-diethylaminocoumarin), N-phenyl-N-ethyl ethanolamine, N-phenylethanolamine, N-tolyldiethanolamine, isoamyl dimethylaminobenzoate, isoamyl diethylaminobenzoate, 3-phenyl-5-benzoylthiotetrazole and 1-phenyl-5-ethoxycarbonylthiotetrazole.

The added amount of the sensitizer based on 100 parts by mass of the compound (A) is preferably 0.05 to 10 parts by mass, more preferably 0.1 to 10 parts by mass. When the added amount of the sensitizer based on 100 parts by mass of the compound (A) is 0.05 parts by mass, the light sensitivity is sufficiently improved. On the other hand, when the added amount of the sensitizer is 10 parts by mass or less, excessive absorption of light at the upper part of the coating film of the conductive paste is suppressed. As a result, the formed conductive pattern is inhibited from being reversely tapered to suppress reduction in adhesion to the substrate.

The conductive paste may contain a solvent. By mixing a solvent, the viscosity of the conductive paste can be appropriately adjusted. The solvent may be added at the end in the process of preparing the paste. By increasing the amount of the solvent, the thickness of the conductive film after drying can be reduced. Examples of the solvent include N,N-dimethylacetamide, N,N-dimethylformamide, N-methyl-2-pyrrolidone, dimethyl imidazolidinone, dimethyl sulfoxide, diethylene glycol monoethyl ether, diethylene glycol monoethyl ether acetate (hereinafter, referred to as “DMEA”), diethylene glycol monomethyl ether acetate, γ-butyrolactone, ethyl lactate, ethylene glycol mono-n-propyl ether and propylene glycol monomethyl ether acetate. For improving the stability of the conductive paste, an organic solvent having a hydroxyl group is preferable.

Examples of the organic solvent having a hydroxyl group include terpineol, dihydroterpineol, hexylene glycol, 3-methoxy-3-methyl-1-butanol (hereinafter, referred to as “Solfit”), 2,2,4-trimethyl-1,3-pentanediol monoisobutyrate, triethylene glycol monobutyl ether, diethylene glycol mono-2-ethylhexyl ether, diethylene glycol monobutyl ether, ethylene glycol mono-2-ethylhexyl ether, ethylene glycol butyl ether, diethylene glycol ethyl ether, tripropylene glycol methyl ether, tripropylene glycol n-butyl ether, propylene glycol phenyl ether, propylene glycol methyl ether, propylene glycol ethyl ether, propylene glycol n-propyl ether, propylene glycol n-butyl ether, dipropylene glycol n-propyl ether, dipropylene glycol methyl ether, dipropylene glycol n-butyl ether, 2-ethyl-1,3-hexane diol, 1-methoxy-2-propanol, 1-ethoxy-2-propanol, diacetone alcohol, tetrahydrofurfuryl alcohol, isopropyl alcohol, n-propyl alcohol and benzyl alcohol.

The viscosity of the conductive paste may be in a range which allows that the conductive paste can be applied, and when the conductive paste is applied by screen printing, the viscosity thereof is preferably 4,000 to 150,000 mPa·s, more preferably 4,000 to 50,000 mPa·s as a value measured at 3 rpm using a Brookfield viscometer. When the viscosity is less than 4,000 mPa·s, it may be unable to form a coating film on the substrate. In this case, it is preferred to use a method such as spin coating by a spinner, spray coating, roll coating, offset printing, gravure printing or die coating. On the other hand, when the viscosity is more than 150,000 mPa·s, irregularities are generated on the surface of the coating film so that exposure unevenness easily occurs.

The conductive paste may contain additives such as a plasticizer, a leveling agent, a surfactant, a silane coupling agent, an antifoaming agent and a pigment as long as desired properties of the conductive paste are not impaired.

Examples of the plasticizer include dibutyl phthalate, dioctyl phthalate, polyethylene glycol, and glycerin.

Examples of the leveling agent include special vinyl-based polymers and special acryl-based polymers.

Examples of the silane coupling agent include methyltrimethoxysilane, dimethyldiethoxysilane, phenyltriethoxysilane, hexamethyldisilazane, 3-methacryloxypropyltrimethoxysilane, 3-glycidoxypropyltrimethoxysilane, and vinyltrimethoxysilane.

The conductive paste is produced using, for example, a disperser or a kneader such as a three-roll mill, a ball mill, and a planetary ball mill.

A method of producing a conductive pattern using the conductive paste will now be described. First, a method of producing a pattern will be described. The method of producing a pattern includes applying the conductive paste onto a substrate, and exposing and developing the conductive paste to obtain a pattern with a line width of 2 to 50 μm. Similarly, the method of producing a conductive pattern includes applying the conductive paste onto a substrate, exposing and developing the conductive paste to obtain a pattern with a line width of 2 to 50 μm, and further heating the resulting pattern at 100 to 300° C. to obtain a conductive pattern. A conductive pattern is also obtained by exposing the pattern to light from a xenon flash tube instead of heating the pattern at 100 to 300° C.

Examples of the substrate include polyethylene terephthalate films (hereinafter, referred to as “PET films”), polyimide films, polyester films, aramid films, epoxy resin substrates, polyether imide resin substrates, polyether ketone resin substrates, polysulfone-based resin substrates, glass substrates, silicon wafers, alumina substrates, aluminum nitride substrates, silicon carbide substrates, decorative layer-formed substrates and insulating layer-formed substrates.

Examples of the method of applying the conductive paste to the substrate include spin coating by a spinner, spray coating, roll coating and screen printing, and coating by a blade coater, a die coater, a calender coater, a meniscus coater or a bar coater. The thickness of the resulting coating film may be appropriately determined according to, for example, a coating method, or a total solid concentration or a viscosity of the conductive paste. The thickness after drying is preferably 0.1 to 50 m. Preferably, the conductive paste is applied by screen printing to obtain a thickness in the above-mentioned range. The thickness can be measured using a probe type step profiler such as SURFCOM (registered trademark) 1400 (manufactured by TOKYO SEIMITSU CO., LTD.). More specifically, the film thickness is measured at randomly selected three positions using a probe type step profiler (measurement length: 1 mm; scanning speed: 0.3 mm/sec), and an average value thereof is defined as a thickness.

When the conductive paste contains a solvent, it is preferable to volatilize the solvent by drying the resulting coating film. Examples of the method of volatilizing and removing a solvent by drying the resulting coating film include heating/drying by an oven, a hot plate, an infrared ray or the like, and vacuum drying. The heating temperature is preferably 50 to 180° C., and the heating time is preferably 1 minute to several hours.

The resulting coating film is exposed via a pattern forming mask by photolithography. The light source for exposure is preferably an i ray (365 nm), a h ray (405 nm) or g ray (436 nm) from a mercury lamp.

The exposed coating film is developed using a developer, and an unexposed part is dissolved and removed to form on a substrate a desired pattern with a line width of 2 to 50 μm. Examples of the development method include alkali development and organic development. Examples of the developer to be used for alkali development include aqueous solutions of tetramethylammonium hydroxide, diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine, and hexamethylenediamine. To these aqueous solutions may be added a polar solvent such as N-methyl-2-pyrrolidone, N,N-dimethylformamide, N,N-dimethylacetamide, dimethyl sulfoxide or γ-butyrolactone, an alcohol such as methanol, ethanol or isopropanol, an ester such as ethyl lactate or propylene glycol monomethyl ether acetate, a ketone such as cyclopentanone, cyclohexanone, isobutyl ketone or methyl isobutyl ketone, or a surfactant.

Examples of the developer to be used for organic development include polar solvents such as N-methyl-2-pyrrolidone, N-acetyl-2-pyrrolidone, N,N-dimethylacetamide, N,N-dimethylformamide, dimethyl sulfoxide, and hexamethylphosphortriamide, and mixed solutions of these polar solvents and methanol, ethanol, isopropyl alcohol, xylene, water, methyl carbitol or ethyl carbitol.

Examples of the development method include a method in which a developer is sprayed to the surface of a coating film while a substrate is left at rest or rotated, a method in which a substrate is immersed in a developer, and a method in which a substrate is immersed in a developer while an ultrasonic wave is applied thereto.

The pattern obtained by development may be subjected to a rinsing treatment with a rinsing liquid. Examples of the rinsing liquid include water, and aqueous solutions obtained by adding to water an alcohol such as ethanol and isopropyl alcohol, or an ester such as ethyl lactate and propylene glycol monomethyl ether acetate.

By heating the resulting pattern at 100 to 300° C., conductivity is exhibited to obtain a conductive pattern. The heating temperature for curing is preferably 100 to 180° C. When the heating temperature is lower than 100° C., curing/shrinkage of the photosensitive organic compound or the like as an organic component is insufficient so that the resistivity cannot be reduced. On the other hand, when the heating temperature is higher than 300° C., a substrate having low heat resistance cannot be used. The heating temperature is preferably 180° C. or lower for suppressing damage to the substrate by heating. The heating time is preferably 1 minute to several hours. Examples of the method of heating the resulting pattern include heating/drying by an oven, an inert oven, a hot plate, an infrared ray or the like and vacuum drying.

By exposing the resulting pattern to light from a xenon flash tube, conductivity is also exhibited to obtain a conductive pattern. The exposure time in this case may be appropriately determined according to an irradiation energy amount while damage to the substrate and the pattern is taken into consideration. The exposure time is preferably 0.01 to 10000 msec. To suppress damage to the substrate and the pattern, it is preferable that irradiation of light from a xenon flash tube is pulse irradiation, and it is more preferable that the irradiation energy per pulse is 2.0 J/cm² or less.

As a process of ensuring that the resulting pattern exhibits conductivity, heating at 100 to 300° C. may be performed in combination with exposure to light from a xenon flash tube.

The conductive pattern produced using the conductive paste and the conductive pattern produced by the method of producing a conductive pattern are each suitably used as a sensor, particularly as a detection sensor in peripheral wiring for a touch panel or a touch panel display section. Examples of the type of a touch panel include a resistive film type, an optical type, an electromagnetic induction type, and an electrostatic capacitance type. Particularly in an electrostatic capacitance type touch panel, fine wiring is required, and therefore the conductive paste which can be processed into a fine pattern of 50 μm or less is more suitably used. In a touch panel including the conductive pattern as peripheral wiring with a pitch (wiring width+width between wiring lines) of 100 μm or less, the frame width can be narrowed and the display section can be widened. In a display section of a touch panel including the conductive pattern as a detection sensor with a width of 10 μm or less, satisfactory visibility can be achieved with a low cost.

### EXAMPLES

Our pastes, patterns, methods and sensors will be described below more in detail by way of examples and comparative examples. This disclosure is not limited to these examples.

Evaluation methods used in examples and comparative examples are as follows.

### Method of Evaluating Patterning Performance

A conductive paste was applied onto a substrate such that the dried film had a thickness of 5 μm, and the thus obtained conductive paste coating film was dried in a drying oven at 100° C. for 5 minutes. One unit was defined as linear transparent patterns arranged with a fixed line-and-space (hereinafter, referred to as “L/S”), and the dried coating film was exposed via photomasks having nine units having different L/S values, respectively and was developed to obtain nine patterns having different L/S values. The L/S values of the units of the photomasks were set to 500/500, 250/250, 100/100, 50/50, 40/40, 30/30, 25/25, 20/20, 15/15, 10/10, 8/8 and 5/5 (each showing a line width (m)/interval (m)). The obtained patterns were observed with an optical microscope to identify a pattern which was free from residues between patterns and free from pattern peeling and had the smallest L/S value, and the L/S value was defined as a development-enabling L/S value. Exposure was performed over the entire line at an exposure amount of 150 mJ/cm² (in terms of a wavelength of 365 nm) using exposure equipment (PEM-6M manufactured by UNION OPTICAL CO., LTD.), and development was performed by immersing a substrate in a 0.2% by mass Na₂CO₃ solution for 30 seconds, and then subjecting the substrate to a rinsing treatment with ultrapure water.

### Method of Evaluating Resistivity

A conductive paste was applied onto a substrate such that the dried film had a thickness of 5 μm, and the thus obtained conductive paste coating film was dried in a drying oven at 100° C. for 5 minutes. The dried coating film was exposed via a photomask, and developed to obtain a pattern. The obtained pattern was heated at 140° C. for 30 minutes (the pattern was irradiated with light from a xenon flash tube for 0.3 msec with 1.0 J/cm² when a PET substrate was used) to exhibit conductivity, thereby obtaining a conductive pattern for measurement of a resistivity. The obtained conductive pattern had a line width of 0.400 mm and a line length of 80 mm.

Conditions for exposure and development were the same as those in the method of evaluating patterning performance. To the ends of the obtained conductive pattern for measurement of a resistivity, an ohmmeter was connected to measure a resistance value, and a resistivity was calculated based on the following Formula (1):

Resistivity=resistance value×film thickness×line width/line length (1).

The line width is an average value obtained by observing line widths at three random positions with an optical microscope, and analyzing image data.

### Method of Evaluating Migration Resistance

A conductive paste was applied onto a substrate such that the dried film had a thickness of 5 μm, and the thus obtained conductive paste coating film was dried in a drying oven at 100° C. for 5 minutes. The dried coating film was exposed via a photomask having a comb-like pattern, and developed to obtain a comb-like pattern. The obtained pattern was heated at 140° C. for 30 minutes (the pattern was irradiated with light from a xenon flash tube for 0.3 msec with 1.0 J/cm² when a PET substrate was used) to exhibit conductivity, thereby obtaining a conductive pattern for evaluation of migration resistance. The obtained conductive pattern had a line width of 50 μm, an interline space width of 50 μm and a line length of 40 mm.

Conditions for exposure and development were the same as those in the method of evaluating patterning performance. An ultra-high ohmmeter (R8340 manufactured by Advantest Corporation) was connected to the ends of the obtained conductive pattern for measurement of migration resistance, a current was made to pass with an applied voltage DC of 20 V, the conductive pattern was exposed for 60 minutes under a constant temperature and humidity of 85° C. and 85 RH %, and a change of the conductive pattern was then observed. A sample in which a dendrite or a short-circuit occurred was rated B, and a sample which was not changed was rated A.

### Method of Evaluating Time-Dependent State Change of Conductive Paste

A sample in which there was almost no change in the state of the conductive paste after kneading and after storage for 2 weeks, and the conductive paste was viscous, and able to be applied was rated S, a sample in which slight separation of the solid occurred to form a lump on the bottom of a conductive paste storage container, but the conductive paste was able to be applied when mixed was rated A, and a sample in which the whole conductive paste was considerably hard, and was difficult to mix, or gelated so that the conductive paste was unable to be applied was rated B. A sample in which the conductive paste started solidifying within an hour after kneading, and was changed to the extent that the conductive paste was unable to be applied was also rated B.

Materials used in examples and comparative examples are as follows.

### Compound (A)

### Synthesis Example 1

Copolymerization ratio (mass basis): ethyl acrylate (hereinafter, referred to as “EA”)/2-ethylhexyl methacrylate (hereinafter, referred to as “2-EHMA”)/styrene (hereinafter, referred to as “St”)/glycidyl methacrylate (hereinafter, referred to as “GMA”)/acrylic acid (hereinafter, referred to as “AA”)=20/40/20/5/15

In a reaction vessel in a nitrogen atmosphere, 150 g of DMEA was added and the temperature was elevated to 80° C. using an oil bath. To this was added dropwise for 1 hour a mixture including 20 g of EA, 40 g of 2-EHMA, 20 g of St, 15 g of AA, 0.8 g of 2,2′-azobisisobutyronitrile and 10 g of DMEA. After completion of the dropwise addition, a polymerization reaction was further carried out for 6 hours. Thereafter, 1 g of hydroquinone monomethyl ether was added to stop the polymerization reaction. Subsequently, a mixture including 5 g of GMA, 1 g of triethyl benzyl ammonium chloride and 10 g of DMEA was added dropwise for 0.5 hours. After completion of the dropwise addition, an addition reaction was further carried out for 2 hours. The obtained reaction solution was refined with methanol to remove unreacted impurities, and dried under vacuum for 24 hours to obtain a compound (A-1) having a carboxyl group and an unsaturated double bond. The acid value of the obtained compound (A-1) was 103 mg KOH/g.

### Synthesis Example 2

Copolymerization ratio (mass basis): tricyclodecane dimethanol diacrylate (IRR214-K; manufactured by DAICEL-CYTEC Co., Ltd.)/modified bisphenol A diacrylate (EBECRYL150; DAICEL-CYTEC Co., Ltd.)/St/AA)=25/40/20/15

In a reaction vessel in a nitrogen atmosphere, 150 g of DMEA was added and the temperature was elevated to 80° C. using an oil bath. To this was added dropwise for 1 hour a mixture including 25 g of IRR214-K, 40 g of EBECRYL150, 20 g of St, 15 g of AA, 0.8 g of 2,2′-azobisisobutyronitrile and 10 g of DMEA. After completion of the dropwise addition, a polymerization reaction was further carried out for 6 hours. Thereafter, 1 g of hydroquinone monomethyl ether was added to stop the polymerization reaction. The obtained reaction solution was refined with methanol to remove unreacted impurities, and dried under vacuum for 24 hours to obtain a compound (A-2) having a carboxyl group and an unsaturated double bond. The acid value of the obtained compound (A-2) was 89 mg KOH/g.

### Synthesis Example 3

Copolymerization ratio (mass basis): ethylene oxide-modified bisphenol A diacrylate (FA-324A manufactured by Hitachi Chemical Company, Ltd.)/EA/GMA/AA=50/10/5/15

In a reaction vessel in a nitrogen atmosphere, 150 g of DMEA was added and the temperature was elevated to 80° C. using an oil bath. To this was added dropwise for 1 hour a mixture including 50 g of ethylene oxide-modified bisphenol A diacrylate, 20 g of EA, 15 g of AA, 0.8 g of 2,2′-azobisisobutyronitrile and 10 g of DMEA. After completion of the dropwise addition, a polymerization reaction was further carried out for 6 hours. Thereafter, 1 g of hydroquinone monomethyl ether was added to stop the polymerization reaction. Subsequently, a mixture including 5 g of GMA, 1 g of triethyl benzyl ammonium chloride and 10 g of DMEA was added dropwise for 0.5 hours. After completion of the dropwise addition, an addition reaction was further carried out for 2 hours. The obtained reaction solution was refined with methanol to remove unreacted impurities, and dried under vacuum for 24 hours to obtain a compound (A-3) having a carboxyl group and an unsaturated double bond. The acid value of the obtained compound (A-3) was 96 mg KOH/g.

### Synthesis Example 4

Copolymerization ratio (mass basis): difunctional epoxy acrylate monomer (Epoxy Ester 3002A manufactured by KYOEISHA CHEMICAL Co., Ltd.)/difunctional epoxy acrylate monomer (Epoxy Ester 70PA manufactured by KYOEISHA CHEMICAL Co., Ltd.)/GMA/St/AA=20/40/5/20/15

In a reaction vessel in a nitrogen atmosphere, 150 g of DMEA was added and the temperature was elevated to 80° C. using an oil bath. To this was added dropwise for 1 hour a mixture including 20 g of Epoxy Ester 3002A, 40 g of Epoxy Ester 70PA, 20 g of St, 15 g of AA, 0.8 g of 2,2′-azobisisobutyronitrile and 10 g of DMEA. After completion of the dropwise addition, a polymerization reaction was further carried out for 6 hours. Thereafter, 1 g of hydroquinone monomethyl ether was added to stop the polymerization reaction. Subsequently, a mixture including 5 g of GMA, 1 g of triethyl benzyl ammonium chloride and 10 g of DMEA was added dropwise for 0.5 hours. After completion of the dropwise addition, an addition reaction was further carried out for 2 hours. The obtained reaction solution was refined with methanol to remove unreacted impurities, and dried under vacuum for 24 hours to obtain a compound (A-4) having a carboxyl group and an unsaturated double bond. The acid value of the obtained compound (A-4) was 101 mg KOH/g.

### Compound (B)

(B-1) 1-(2-aminoethyl)piperazine
(B-2) 6-amino-1-methyluracil
(B-3) EPOMIN (registered trademark) SP-200 (manufactured by NIPPON SHOKUBAI CO., LTD.)

### (B-4) Benzotriazole

### Compound (C)

(C-1) Epoxy resin (JER828 (epoxy equivalent: 188); manufactured by Mitsubishi Chemical Corporation)
(C-2) Epoxy resin (ADEKA RESIN EPR-21 (epoxy equivalent: 210); manufactured by ADEKA CORPORATION)
Silver-coated particles
Silver-coated particles shown in Table 1
Photopolymerization initiator
IRGACURE (registered trademark) 369 (hereinafter, referred to as “IC369”) (manufactured by BASF Japan Ltd.)
N-1919 (manufactured by ADEKA CORPORATION)

### Monomer

LIGHT ACRYLATE BP-4EA (manufactured by KYOEISHA CHEMICAL Co., Ltd.)

### Solvent

DMEA (manufactured by Tokyo Chemical Industry Co., Ltd.)
Solfit (manufactured by KURARAY CO., LTD.)

### Example 1

In a 100 mL clean bottle, 10.0 g of the compound (A-1), 0.50 g of IC369 and 23.5 g of DMEA were added and mixed by “Awatori Rentaro” (registered trademark) (ARE-310; manufactured by THINKY CORPORATION) to obtain 34 g of a resin solution (solid content: 50% by mass). The composition is shown in Table 1.

34 g of the obtained resin solution and 24.5 g of silver-coated particles (copper-nickel alloy) were mixed together, and kneaded using a three-roll mill (EXAKT M-50; manufactured by EXAKT) to obtain 58.5 g of a conductive paste. The viscosity after kneading was 25,000 mPa·s.

Patterning performance, resistivity and adhesion to ITO for the conductive pattern were evaluated using the obtained conductive paste. The development-enabling L/S value serving as an evaluation index for patterning performance was 15/15 μm, and it was thus confirmed that proper pattern processing was performed. The resistivity of the conductive pattern was 7.2×10−5 Ωcm. The results of performing evaluations are shown in Table 3.

### Examples 2 to 9 and 12 to 15

Conductive pastes having compositions as shown in Table 1 were produced in the same manner as in Example 1, and were evaluated in the same manner as in Example 1. The results thereof are shown in Table 3.

### Examples 10 and 11

Conductive pastes having compositions as shown in Table 1 were produced in the same manner as in Example 1, and evaluated in the same manner as in Example 1 except that the conductive paste was irradiated with light from a xenon flash tube instead of being heated. The results thereof are shown in Table 3.

### Comparative Examples 1 to 9

Conductive pastes having compositions as shown in Table 2 were produced in the same manner as in Example 1, and were evaluated in the same manner as in Example 1. The results thereof are shown in Table 3.

From the conductive paste of each of Examples 1 to 15, a conductive pattern excellent in patterning performance, resistivity and migration resistance was formed. The conductive patterns formed from the conductive pastes of Comparative Examples 1 to 3, 5 to 7 and 9 were poor in migration resistance.

In Comparative Example 4, there was no problem as to migration resistance, but the resistivity was considerably high.

In Comparative Example 8, a gel-like paste was obtained, and therefore it was unable to apply the paste so that it was unable to evaluate patterning performance.

TABLE 1

| | | Compound (B) | | Compound (C) | | Silver-coated particles | |
|---|---|---|---|---|---|---|---|
| | | | Parts by mass based | | Parts by mass based | Ratio of | |
| | Compound (A) | | on 100 parts by | | on 100 parts by | silver | |
| | Type | Type | mass of compound (A) | Type | mass of compound (A) | (% by mass) | Core |
| Example 1 | (A-1) | — | — | — | — | 30 | CuNi alloy |
| Example 2 | (A-1) | (B-1) | 5 | — | — | 30 | CuNi alloy |
| Example 3 | (A-2) | (B-4) | 5 | (C-1) | 30 | 20 | CuNi alloy |
| Example 4 | (A-3) | (B-4) | 5 | (C-1) | 30 | 10 | CuNi alloy |
| Example 5 | (A-4) | (B-1) | 5 | (C-1) | 30 | 40 | CuNi alloy |
| Example 6 | (A-1) | (B-2) | 5 | (C-2) | 30 | 30 | CuZn alloy |
| Example 7 | (A-1) | (B-1) | 5 | — | — | 30 | CuZn alloy |
| Example 8 | (A-1) | (B-3) | 5 | — | — | 30 | CuZn alloy |
| Example 9 | (A-1) | (B-3) | 5 | — | — | 30 | CuZn alloy |
| Example 10 | (A-1) | (B-3) | 5 | — | — | 30 | CuZn alloy |
| Example 11 | (A-1) | (B-4) | 5 | (C-2) | 50 | 40 | Cu |
| Example 12 | (A-2) | — | — | — | — | 20 | CuZn alloy |
| Example 13 | (A-2) | — | — | (C-2) | 30 | 20 | CuZn alloy |
| Example 14 | (A-2) | (B-1) | 15 | (C-1) | 50 | 30 | CuZn alloy |
| Example 15 | (A-2) | (B-3) | 7 | (C-2) | 70 | 30 | CuZn alloy |
| Example 16 | (A-2) | — | — | — | — | 30 | CuZn alloy |
| Example 17 | (A-2) | (B-1) | 5 | — | — | 30 | CuZn alloy |
| Example 18 | (A-2) | (B-3) | 10 | — | — | 20 | CuZn alloy |
| Example 19 | (A-3) | — | — | (C-2) | 70 | 30 | CuZn alloy |
| Example 20 | (A-3) | — | — | (C-1) | 70 | 10 | CuZn alloy |

| | Silver-coated particles | | Photopolymerization initiator | | Solvent | |
|---|---|---|---|---|---|---|
| | Ratio to total | Volume | | Parts by mass based | | Ratio to |
| | solid content | average particle | | on 100 parts by | | conductive paste |
| | (% by mass) | size (μm) | Type | mass of compound (A) | Type | (% by mass) |
| Example 1 | 70 | 2.0 | IC369 | 5 | DMEA | 40 |
| Example 2 | 70 | 2.0 | IC369 | 5 | DMEA | 40 |
| Example 3 | 70 | 2.0 | IC369 | 5 | Solfit | 30 |
| Example 4 | 70 | 2.0 | IC369 | 5 | Solfit | 30 |
| Example 5 | 70 | 2.0 | IC369 | 5 | DMEA | 30 |
| Example 6 | 48 | 1.0 | IC369 | 7 | DMEA | 40 |
| Example 7 | 55 | 1.5 | IC369 | 5 | DMEA | 30 |
| Example 8 | 60 | 2.0 | IC369 | 5 | DMEA | 30 |
| Example 9 | 75 | 3.0 | IC369 | 5 | DMEA | 30 |
| Example 10 | 60 | 2.0 | IC369 | 5 | DMEA | 30 |
| Example 11 | 75 | 2.5 | IC369 | 5 | Solfit | 40 |
| Example 12 | 70 | 2.0 | IC369 | 5 | DMEA | 40 |
| Example 13 | 70 | 2.0 | IC369 | 5 | DMEA | 40 |
| Example 14 | 70 | 2.0 | IC369 | 5 | DMEA | 40 |
| Example 15 | 70 | 2.0 | N-1919 | 5 | DMEA | 40 |
| Example 16 | 40 | 2.0 | IC369 | 5 | DMEA | 40 |
| Example 17 | 80 | 2.0 | N-1919 | 5 | DMEA | 40 |
| Example 18 | 40 | 2.0 | N-1919 | 5 | DMEA | 40 |
| Example 19 | 75 | 3.0 | IC369 | 5 | Solfit | 30 |
| Example 20 | 70 | 2.0 | IC369 | 5 | DMEA | 30 |

TABLE 2

| | | Compound (B) | | Compound (C) | | Silver-coated particles | |
|---|---|---|---|---|---|---|---|
| | | | Parts by mass based | | Parts by mass based | Ratio of | |
| | Compound (A) | | on 100 parts by | | on 100 parts by | silver | |
| | Type | Type | mass of compound (A) | Type | mass of compound (A) | (% by mass) | Core |
| Comparative | (A-1) | — | — | — | — | 50 | Cu |
| Example 1 | | | | | | | |
| Comparative | (A-1) | — | — | — | — | 50 | Cu |
| Example 2 | | | | | | | |
| Comparative | (A-1) | — | — | — | — | 50 | Cu |
| Example 3 | | | | | | | |
| Comparative | (A-1) | — | — | — | — | 5 | CuZn alloy |
| Example 4 | | | | | | | |
| Comparative | (A-1) | — | — | — | — | 50 | Cu |
| Example 5 | | | | | | | |
| Comparative | (A-1) | — | — | — | — | 50 | Ni |
| Example 6 | | | | | | | |
| Comparative | (A-1) | — | — | — | — | 50 | SiO₂ |
| Example 7 | | | | | | | |
| Comparative | (A-1) | — | — | — | — | 0 | Cu |
| Example 8 | | | | | | | |
| Comparative | (A-1) | — | — | — | — | 100 | Ag |
| Example 9 | | | | | | | |

| | Silver-coated particles | | Photopolymerization initiator | | Solvent | |
|---|---|---|---|---|---|---|
| | Ratio to total | Volume | | Parts by mass based | | Ratio to |
| | solid content | average particle | | on 100 parts by | | conductive paste |
| | (% by mass) | size (μm) | Type | mass of compound (A) | Type | (% by mass) |
| Comparative | 60 | 2.0 | IC369 | 5 | DMEA | 30 |
| Example 1 | | | | | | |
| Comparative | 30 | 2.0 | IC369 | 5 | DMEA | 30 |
| Example 2 | | | | | | |
| Comparative | 90 | 2.0 | IC369 | 5 | DMEA | 30 |
| Example 3 | | | | | | |
| Comparative | 60 | 2.0 | IC369 | 5 | Solfit | 30 |
| Example 4 | | | | | | |
| Comparative | 60 | 5.0 | IC369 | 5 | DMEA | 30 |
| Example 5 | | | | | | |
| Comparative | 60 | 2.0 | IC369 | 5 | DMEA | 30 |
| Example 6 | | | | | | |
| Comparative | 60 | 2.0 | IC369 | 5 | DMEA | 30 |
| Example 7 | | | | | | |
| Comparative | 60 | 2.0 | IC369 | 5 | Solfit | 30 |
| Example 8 | | | | | | |
| Comparative | 60 | 2.0 | IC369 | 5 | DMEA | 30 |
| Example 9 | | | | | | |

TABLE 3

| | | Resistivity | Development- | Migration | State change of paste |
|---|---|---|---|---|---|
| | Substrate | (Ωcm) | enabling L/S (μm) | resistance | after one weak |
| Example 1 | Glass | 1.0 × 10⁻⁴ | 30/30 | A | A |
| Example 2 | Glass | 5.4 × 10⁻⁵ | 30/30 | A | S |
| Example 3 | Glass | 8.2 × 10⁻⁵ | 20/20 | A | S |
| Example 4 | Glass | 9.4 × 10⁻⁵ | 20/20 | A | S |
| Example 5 | Glass | 4.5 × 10⁻⁵ | 20/20 | A | S |
| Example 6 | Glass | 1.1 × 10⁻⁴ | 8/8 | A | S |
| Example 7 | Glass | 9.2 × 10⁻⁵ | 20/20 | A | S |
| Example 8 | Glass | 8.0 × 10⁻⁵ | 30/30 | A | S |
| Example 9 | Glass | 7.5 × 10⁻⁵ | 40/40 | A | S |
| Example 10 | PET film | 6.7 × 10⁻⁵ | 30/30 | A | S |
| Example 11 | PET film | 5.7 × 10⁻⁵ | 20/20 | A | S |
| Example 12 | Glass | 1.5 × 10⁻⁴ | 30/30 | A | A |
| Example 13 | Glass | 1.8 × 10⁻⁵ | 10/10 | A | A |
| Example 14 | Glass | 6.4 × 10⁻⁵ | 15/15 | A | S |
| Example 15 | Glass | 6.0 × 10⁻⁵ | 10/10 | A | S |
| Example 16 | Glass | 1.9 × 10⁻⁴ | 10/10 | A | A |
| Example 17 | Glass | 7.0 × 10⁻⁵ | 50/50 | A | S |
| Example 18 | Glass | 7.0 × 10⁻⁵ | 10/10 | A | S |
| Example 19 | Glass | 1.3 × 10⁻⁴ | 20/20 | A | A |
| Example 20 | Glass | 1.8 × 10⁻⁴ | 15/15 | A | A |
| Comparative | Glass | 5.5 × 10⁻⁵ | 20/20 | B | A |
| Example 1 | | | | | |
| Comparative | Glass | 6.0 × 10⁻⁵ | 20/20 | B | A |
| Example 2 | | | | | |
| Comparative | Glass | 6.2 × 10⁻⁵ | 20/20 | B | A |
| Example 3 | | | | | |
| Comparative | Glass | 2.1 × 10⁻³ | 20/20 | A | B |
| Example 4 | | | | | |
| Comparative | Glass | 7.9 × 10⁻³ | 50/50 | B | A |
| Example 5 | | | | | |
| Comparative | Glass | 5.8 × 10⁻⁵ | 20/20 | B | A |
| Example 6 | | | | | |
| Comparative | Glass | 3.0 × 10⁻⁴ | 20/20 | B | A |
| Example 7 | | | | | |
| Comparative | Glass | — | — | — | B |
| Example 8 | | | | | |
| Comparative | Glass | 4.0 × 10⁻⁵ | 20/20 | B | S |
| Example 9 | | | | | |

### INDUSTRIAL APPLICABILITY

The conductive paste can be suitably used to produce a conductive pattern for a detection sensor in a touch panel display section, peripheral wiring for a touch panel or the like.

1-8. (canceled)

9. A conductive paste comprising:
silver-coated particles in which a conductive core is coated with silver; and
a photosensitive organic compound, wherein
a ratio of silver to the silver-coated particles is 10 to 45% by mass.

10. The conductive paste according to claim 9, wherein the conductive core contains copper.

11. The conductive paste according to claim 9, wherein a ratio of the silver-coated particles to the total solid content is 40 to 80% by mass.

12. A method of producing a pattern comprising applying the conductive paste according to claim 9 onto a substrate, and exposing and developing the conductive paste to obtain a pattern with a line width of 2 to 50 μm.

13. A method of producing a conductive pattern comprising applying the conductive paste according to claim 9 onto a substrate, exposing and developing the conductive paste to obtain a pattern with a line width of 2 to 50 μm, and further heating the pattern at 100 to 300° C. to obtain a conductive pattern.

14. A method of producing a conductive pattern comprising applying the conductive paste according to claim 9 onto a substrate, exposing and developing the conductive paste to obtain a pattern with a line width of 2 to 50 μm, and further exposing the resulting pattern to light from a xenon flash tube to obtain a conductive pattern.

15. A sensor comprising a conductive pattern produced using the conductive paste according to claim 9.

16. A sensor comprising a conductive pattern produced by the method according to claim 13.

17. A sensor comprising a conductive pattern produced by the method according to claim 14.

18. The conductive paste according to claim 10, wherein a ratio of the silver-coated particles to the total solid content is 40 to 80% by mass.

19. A method of producing a pattern comprising applying the conductive paste according to claim 10 onto a substrate, and exposing and developing the conductive paste to obtain a pattern with a line width of 2 to 50 μm.

20. A method of producing a pattern comprising applying the conductive paste according to claim 11 onto a substrate, and exposing and developing the conductive paste to obtain a pattern with a line width of 2 to 50 μm.

21. A method of producing a conductive pattern comprising applying the conductive paste according to claim 10 onto a substrate, exposing and developing the conductive paste to obtain a pattern with a line width of 2 to 50 μm, and further heating the pattern at 100 to 300° C. to obtain a conductive pattern.

22. A method of producing a conductive pattern comprising applying the conductive paste according to claim 11 onto a substrate, exposing and developing the conductive paste to obtain a pattern with a line width of 2 to 50 μm, and further heating the pattern at 100 to 300° C. to obtain a conductive pattern.

23. A method of producing a conductive pattern comprising applying the conductive paste according to claim 10 onto a substrate, exposing and developing the conductive paste to obtain a pattern with a line width of 2 to 50 μm, and further exposing the resulting pattern to light from a xenon flash tube to obtain a conductive pattern.

24. A method of producing a conductive pattern comprising applying the conductive paste according to claim 11 onto a substrate, exposing and developing the conductive paste to obtain a pattern with a line width of 2 to 50 μm, and further exposing the resulting pattern to light from a xenon flash tube to obtain a conductive pattern.

25. A sensor comprising a conductive pattern produced using the conductive paste according to claim 10.

26. A sensor comprising a conductive pattern produced using the conductive paste according to claim 11.
